(19) United States
(12) Patent Application Publication
(10) Pub. No.: US 2017/0333936 A1
(43) Pub. Date: Nov. 23, 2017

(54) SEGMENTED OR SELECTED-AREA COATING

(71) Applicant: FAS Holdings Group, LLC, Dallas, TX (US)

(72) Inventors: Gregory M. GIBSON, Dallas, TX (US); Scott A. SNODGRASS, Garland, TX (US)

(21) Appl. No.: 15/670,564

(22) Filed: Aug. 7, 2017

Related U.S. Application Data
(63) Continuation-in-part of application No. 13/367,854, filed on Feb. 7, 2012.
Application No. 13/367,854 is a continuation of application No. PCT/US2010/044748, filed on Aug. 6, 2010.
(60) Provisional application No. 61/232,370, filed on Aug. 7, 2009.

(51) Int. Cl. B05C 5/02; H01L 21/67; H01L 27/12; B05D 1/26; B05C 3/20; B05C 19/06; B05C 11/02

(52) U.S. Cl. CPC B05C 5/0216; H01L 27/1292; H01L 21/6715; B05D 1/265; B05C 19/06; B05C 11/021; B05C 3/20

(57) ABSTRACT

An apparatus for forming selectively coated areas on a substrate comprises an extrudate remover configured to selectively remove coating from a selected portion of the substrate. A chuck is configured to secure the substrate. A coating die is arranged proximal the substrate and is in fluid communication with a source of fluid extrudate. During relative motion between the substrate and the coating die, fluid extrudate is deposited onto the substrate. A controller is configured to selectively control the relative motion between the substrate and coating remover, and to control operation of the extrudate remover. The invention also provides a method of forming selectively coated areas on a substrate comprising the steps of inducing relative movement between a coating dispenser and the substrate, applying fluid material from the coating dispenser onto the substrate during the relative movement, and selectively removing a portion of the applied fluid from the substrate.

### REFERENCE TO RELATED APPLICATIONS

This application is a continuation-in-part of application Ser. No. 13/367,854 filed Feb. 7, 2012, which is a continuation of PCT application PCT/US2010/044748, filed Aug. 6, 2010 and also claims priority to provisional application Ser. No. 61/232,370 filed Aug. 7, 2009.

### FIELD OF THE INVENTION

The present invention relates generally to the formation of selected coated areas or segments on substrates. More particularly, the present invention relates to methods and apparatus for forming selectively coated areas on substrates with thin films by controlled extrusion of a fluid onto the substrate and controlled removal of selected portions of that fluid from the substrate.

### BACKGROUND OF THE INVENTION

FAS Holdings Group, LLC of Dallas, Tex. pioneered a method of coating thin substrates with thin-film coatings by “extrusion.” In this extrusion process, a coating or extrusion die (also known as slot die) and substrate are moved relative to one another at a precisely controlled rate. Extrudate or coating material is extruded or dispensed in a bead from the die and onto the substrate at a controlled rate. The software-controlled relative movement and dispense rates permit use of the surface tension or capillary action of the extrudate to produce a coating on the substrate of extremely uniform thin-film (measured in microns) thickness.

This extrusion technology is an excellent alternative to the prior spinning process in the manufacture of flat-panel and thin-film displays, such as LCD, LED, OLED, and PLED screens for computer, television and other display applications. Because coatings frequently consist of expensive materials and often are applied to large, and sometimes thin and delicate substrates, such as glass and plastics, spinning is an undesirable process because it utilizes only a very small percentage of the dispensed coating material and subjects such substrates to forces that can and often do break them, leading to high material waste and increased cost.

FAS′ successor, nTact, and others have continued to develop many facets of the extrusion process. The extrusion process described above typically produces a “monolithic” or uninterrupted coating that is almost or entirely coextensive with (covers the surface of) the substrate. As thin-film displays, solid state lighting and photovoltaic technologies evolve, there has arisen a need to produce “segmented” coatings that coat only selected areas of a substrate. Commonly assigned U.S. Pat. No. 7,169,229 suggests that by “shimming” or modifying the die to produce multiple extrusion or coating beads, multiple smaller areas could be coated simultaneously in a coating apparatus designed to coat a single, larger area. This is a form of “segmented” coating, but has been thus far limited to orthogonal shapes (squares and rectangles corresponding to the size and shape of the smaller desired coating areas) due to the limitations of the extrusion or coating apparatus.

The present invention provides a method and apparatus for producing segmented coatings that does not suffer from the shortcomings of the prior art.

### SUMMARY OF THE INVENTION

It is a general object of the present invention to provide an apparatus and method for coating substrates having an improved ability to form two- and three-dimensional shapes on the substrate.

This and other objects of the present invention are achieved by an apparatus for forming selectively coated areas on a substrate that comprises an extrudate or coating remover configured to selectively remove extrudate or coating from a selected portion of the substrate. A chuck is configured to secure the substrate. A coating dispenser is arranged proximal the substrate and is in fluid communication with a source of fluid extrudate. During relative motion between the substrate and the coating dispenser, fluid is deposited onto the substrate. A controller is configured to selectively control the relative motion between the substrate and extrudate remover, and to control operation of the extrudate remover.

The invention also provides a method of forming selectively coated areas on a substrate comprising the steps of inducing relative movement between a coating dispenser and the substrate, applying fluid material from the coating dispenser onto the substrate during the relative movement, and selectively removing a portion of the applied fluid from the substrate.

Other objects, features, and advantages of the present invention will become apparent with reference to the Figures, and to the Detailed Description, which follow.

### BRIEF DESCRIPTION OF THE DRAWINGS

FIG. 1 is a perspective view of a coating or extrusion apparatus according to the present invention.

FIG. 2 is an enlarged perspective view of a crossbar and coating or extrudate remover portion of the apparatus illustrated in FIG. 1.

FIGS. 3A and 3B are rear and front elevation views of the “solvent knife” portion of the extrusion apparatus of FIG. 1.

FIG. 4 is a flowchart depicting the steps of the method of the present invention.

FIG. 5 is an enlarged perspective view of another embodiment of the invention, illustrating the crossbar and coating or extrudate remover portion.

FIG. 6 is a plan view of a extrudate remover according the the embodiment of the invention illustrated in FIG. 5.

FIG. 7 is a schematic depiction of the operation of the extrudate remover of FIGS. 5 and 6.

FIG. 8 is a bottom plan view of an array of extrudate removers of FIGS. 5 through 7.

FIG. 9 is a perspective view of another array of extrudate removers of FIGS. 5 through 7.

FIG. 10 is a perspective view of an extrudate remover according to a preferred embodiment of the present invention.

FIG. 11 is a perspective view, partially in section, of the extrudate remover of FIG. 10.

### DETAILED DESCRIPTION OF THE INVENTION

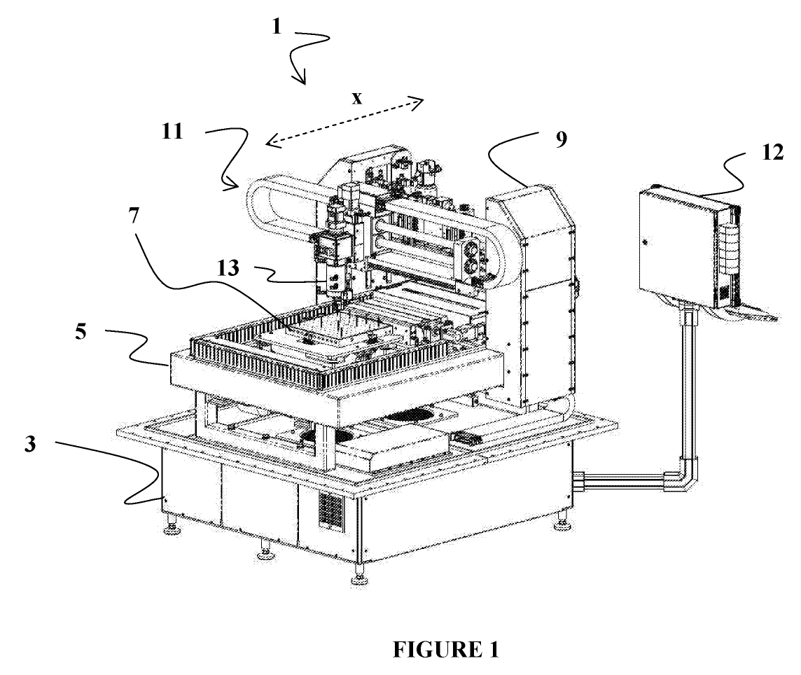

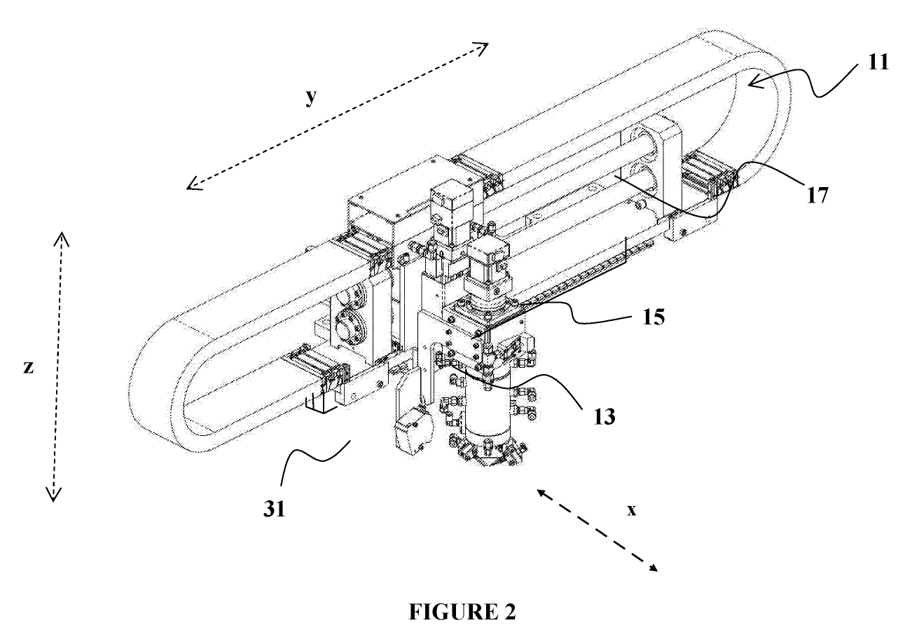

Referring now to the Figures, and specifically to FIGS. 1 and 2, a coater or extrusion apparatus 1 according to an illustrative embodiment of the present invention is shown. Coater 1 generally comprises a base 3, which may house fluid reservoirs, computer components, motors and other apparatus associated with the operation of coater 1. Base 3 is designed to be very precisely leveled and to isolate the remainder of coater 1 from vibration.

A table 5 made of heavy, flat, dimensionally stable material, such as granite, is secured to an upper surface of base 3 and provides a platform for mounting a chuck 7 and a carriage assembly 9. Chuck 7 receives and secures a substrate, typically a very thin piece of glass, relative to carriage assembly 9. The substrate may be a single piece, handled in a “sheet feed” fashion, or may come continuously from a roll (and may be taken up by a roll as well). Chuck 7 may employ vacuum or mechanical means to secure the substrate. Substrate materials include metal, plastic, foil, glass, circuit boards, cardboard, wood, alloy or crystalline, fibrous or materially homogenous platforms. The substrate may be plain and flat or may be patterned, embossed or addressed or printed to render the substrate either active or passive. The substrate may have other active or passive layers to include electrically conducting layers, optical waveguides and polarizers, filters and the like, and these may be in addition to the layers deposited by the techniques described here. Such substrates may produce an effect in concert with the layers that can be utilized to manufacture devices to include RFID devices, circuit boards, active or passive thin-film displays or panels, solid-state lighting, semi-conducting, photovoltaic, emissive, reflecting, or transmissive displays or panels, touchscreen devices, data storage devices and the like.

Preferably, carriage assembly 9 moves fore and aft in FIG. 1 and includes a transverse crossbar assembly 11 that may carry or include an extrusion or coating dispenser or die 15 and an extrudate or coating remover or solvent knife 13 according to the present invention. Die 15 dispenses a fluid coating material or extrudate onto the surface of the substrate at a carefully controlled rate. Coating die 15 may be shimmed, shaped, or modified to provide multiple beads of extrudate, or may deposit only a single bead. Carriage 9 and crossbar 11 also house motors, linear bearings, and other motion control components that move and control die 15 (fore-and-aft or “x” axis) and solvent knife 13 (in fore-and-aft, left-to-right or “y” axis, and up-and-down or “z” axis directions). In a preferred embodiment of the present invention, carriage assembly 9, crossbar 11 and associated die 15 move relative to a substrate secured on chuck 7. By precise, software control of this relative movement, together with precise control of the flow of extrudate from die 11, a precise thin-film coating is applied to the substrate, the coating having a uniform wet-film thickness. The extrudate or coating material may be organic, inorganic, organo-metallic, solvent-based, aqueous-based, colloidal, sol-gel, liquid crystal, dielectric, conducting, non-conducting, semi-conducting, nano-particle containing, solid containing, liquid partition, soap, paste, gum, suspension or foam, hot melt, metal or metal alloy.

A controller or control system 12 is also provided that preferably is personal-computer (PC) and/or programmable logic controller (PLC) based. This controller allows input and control of the software that controls the various motion and control devices involved in inducing relative movement between carriage 9 and a substrate mounted on chuck 7 and table 5. The software also controls fluid flow rates, particularly the dispense rate of the extrudate from extrusion or coating die 15. Other than extrudate remover 13, discussed in greater detail below, coating or extrusion device or apparatus 1 is known and conventional and such a device, again without the remover 13, is available from FAS Holdings Group, LLC of Dallas, Tex., and is described in commonly assigned U.S. Pat. Nos. 7,169,229 and 6,319,323, which are incorporated herein by reference in their entirety.

A major advantage of the extrusion system described above, compared to prior-art “spinning” coating processes, is that the substrate need not be spun or rotated, or moved at all (where carriage 9 and crossbar 11 move relative to substrate and chuck 7) and all relative movement for coating (between die 9 and the substrate) occurs orthogonally, or in the x, y, and z axes or planes, as opposed to the angular relative motion required in spinning processes.

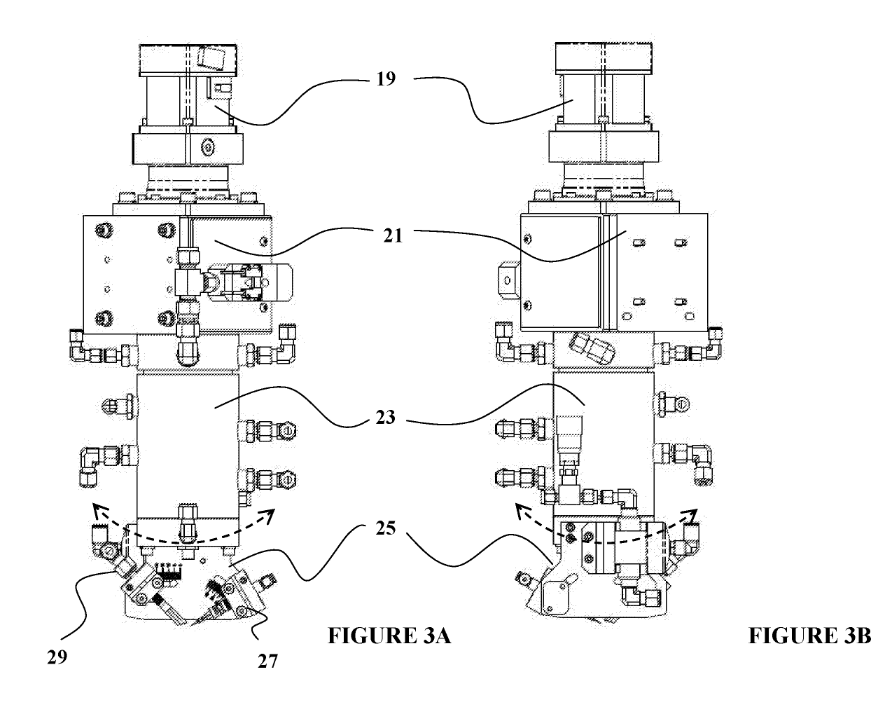

FIGS. 3A and 3B are front and rear elevation views of a “solvent knife” or extrudate remover 13 according to the present invention. Broadly speaking, the purpose of the solvent knife 13 is to remove extrudate after it has been deposited on the substrate. Removal of extrudate subsequent to its deposition enables many of the features of the apparatus according to the present invention. Coating or extrudate remover 13 can be mounted on crossbar 11 of carriage 9 of an “OEM” or purpose-built coating apparatus, or can be retrofit onto the carriage of an existing coating apparatus. Additionally or alternatively, more than one extrudate remover 13 can be provided, all of them mounted on a single carriage and crossbar, or each mounted on a separate apparatus, such as a multi-axis robotic arm or manipulator, or a separate carriage from carriage 9. Each remover 13 may be configured as a separate and independent process station of coating apparatus. These removers can be controlled simultaneously or individually (and independently) depending on the final application or to meet production metrics such as but not exclusive to TACT (Turn Around Cycle Time, which is essentially the throughput of the coating system, typically expressed in seconds per substrate). Further, a remover 13 can be used as a standalone system or in conjunction with other types of coating or deposition apparatus, such as spray coating, roller coating, spin coating, vapor deposition, and the like, where the coating material is not “extruded” but otherwise dispensed or deposited.

According to a preferred and illustrative embodiment of the invention shown in FIGS. 2, 3A and 3B, extrudate remover 13 is mounted on a crossbar 11 portion of carriage 9 with a linear bearing apparatus 17 that permits controlled linear translation of remover 13 independently along the y axis (from left to right and back in FIG. 2) and z axis (from top to bottom and back in FIG. 2). Remover 13 may be propelled or driven by a servomotor or similar controlled device 19 that has integrated encoders for determining and communicating to controller 12 the relative horizontal or y axis position of remover 13. A mounting stage 21 secures remover 13 to linear bearing apparatus 17. A laser interferometry displacement sensor or measurement device 31 is secured to mounting stage 21 for determining and communicating to controller 12 the relative vertical or z axis position of remover 13.

A pneumatic and hydraulic rotary union 23 is mounted below mounting stage 21, which allows rotary union 23 and its associated apparatus to rotate about the z axis, while rotary union 23 is in fluid communication with vacuum (pneumatic) and pressurized liquid (hydraulic) sources (carried in base 3 or carriage 9) and appropriate fluid reservoirs (tubing is omitted from the figures for clarity). Alternatively, union 23 can be mounted above mounting stage 21. A mounting plate 25 extends downwardly from rotary union 23.

A solvent nozzle in the form of a needle 27 is mounted on plate 25 at a user-selectable position (both angle and height) and is in fluid communication through conduits (tubing not shown) with a source of solvent or other fluid for removing coating or extrudate. Solvent nozzle 27 sprays or otherwise deposits a solvent or other fluid that is delivered from the fluid source through the rotary union 23. The solvent or fluid dissolves, disintegrates, or comminutes the extrudate (coating fluid) deposited on the substrate. The extrudate may be partially or wholly solidified or cured. The dissolution may occur by chemical action of the solvent on the extrudate, or by abrasive disintegration or comminution occurring as a result of an abrasive carried in the fluid spray, or a combination of both. The term “disintegration” is intended to encompass both chemical dissolution and abrasive comminution, as well as combinations of the two.

A spray-capture or exhaust tube 29 also is mounted on plate 25 at a user-selectable position (angle is fixed, but horizontal and vertical positions can be changed) and is in fluid communication with a source of vacuum through rotary union 23. Preferably, nozzle or needle 27 is oriented at an angle between 30 and 60 degrees relative to horizontal or the substrate to avoid “splashing” of the solvent or sprayed liquid and to help avoid dripping on the substrate. The angle may be varied depending on process parameters such as the solvent fluid and spray characteristics. Spray capture or exhaust tube 29 removes the dissolved or disintegrated extrudate and the solvent or abrasive fluid from the surface of the substrate, leaving a selected area of reduced coating thickness or bare (as opposed to coated) substrate.

According to this illustrative embodiment of the present invention, extrudate remover 13 sprays or applies a solvent (chosen to dissolve the extrudate) or other liquid, or liquid containing fine abrasive particles, through nozzle 27 to selectively remove extrudate or coating from the substrate. The multi-axis positioning of remover 13 through carriage 9 (x axis), linear bearing 17 (y axis), stage 21 (z axis), and rotary union 23 permits precise positioning of nozzle 27 for very selective removal of selective portions of the extrudate. Exhaust tube 29 provides a vacuum to remove any liquid applied by nozzle 27 and dissolved or comminuted extrudate material.

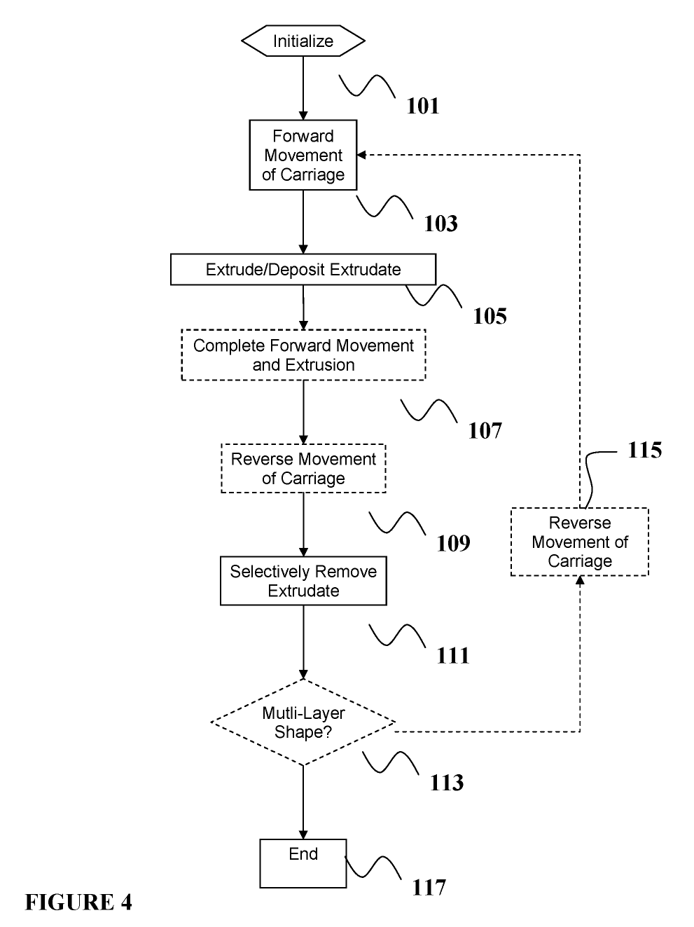

FIG. 4 is a flowchart illustrating the control process employed by the apparatus of FIGS. 1 through 3B to provide extended capability to a generally conventional coating apparatus. The extended capability derives from the ability of extrudate or coating remover to selectively remove extrudate or coating deposited or applied by the more conventional aspects of the coater according to the present invention. This permits making of complex 2-dimensional and 3-dimensional patterns of extrudate upon a substrate, greatly increasing the flexibility of the apparatus according to the present invention.

As with all coating apparatus, the first step in the coating process is to initialize the software and control components, at step 101. At step 103, coating or extrusion is begun by initiating “forward” or x-axis movement of carriage 9 and crossbar 11 over the substrate (alternatively, the substrate and chuck 7 can be moved relative to carriage 9 and crossbar 11, or a combination of relative movements employed). During the “forward” relative movement between the substrate and coating or extrusion die 15 carried by carriage 9 and crossbar 11, extrudate or coating fluid is dispensed, deposited, or extruded at a selected and controlled rate taking into account the velocity and direction of relative movement between carriage 9 and the substrate, at step 105. This permits a highly uniform coating having a uniform wet-film thickness to be deposited on the substrate. The coating may cover the entire surface of the substrate in a monolithic fashion, or be coated on the substrate in a plurality of segments or shapes, such as several squares, rectangles or other more complex shapes. The coating may be accomplished in multiple “passes,” wherein the carriage 9 is moved slightly in the y-axis direction and another forward “pass” made to deposit adjacent, overlapping, or even spaced-apart layers of coating are deposited. Even with relative carriage and substrate movement confined to the orthogonal x, y, and z axes and planes, quite complex shapes can be formed (for purposes of this application, the x and y axes represent movement in a plane parallel to the substrate in lateral and longitudinal directions, while the z axis is perpendicular to the substrate). The formation of more complex two-dimensional (and even three-dimensional) shapes on the substrate is enhanced by the use of the extrudate or coating remover as described below.

At step 107, “forward” (x-axis or combined x- and y-axis) relative movement between carriage 9 and the substrate, together with associated dispensing, deposition, or extrusion is completed. This step may involve “completion” of the extrusion process in the sense that the entire substrate is fully coated with the extrudate (or selected segments or portions of the substrate), or can represent a partial completion or “stopping point” within the process. Accordingly, this step is shown in phantom because it is optional.

After coating at least a portion of the substrate, the selective removal process may begin. At step 109, “reverse” relative movement (x- and/ or y-axis movement in the generally opposite direction from step 107) between carriage 9 and the substrate is initiated. According to the illustrative process, coating of the entire substrate is completed during “forward” relative motion as described in connection with steps 103 and 105. But, as mentioned, only partial completion of the coating process need be undertaken.

Whether completion of the coating process is necessary may depend upon the extrudate or coating fluid being employed and its cure time or physical characteristics. For example, in many or most coating processes, some time must elapse for the beads from die 15 to expand or spread under surface tension or capillary action to “complete” the coating and it is desirable or preferred that the removal step take place after spreading, but while the extrudate or coating is in a “wet” state. In some processes, the extrudate will need to harden or cure prior to attempting removal, sometimes with an additional process step for curing (for example, exposure to UV radiation and the like).

In any event, “reverse” relative movement between carriage and substrate, at step 109, represents a “second pass” over the coated substrate for the purpose of extrudate or coating removal. It need not actually be in the “reverse” or opposite direction of the movement undertaken for coating or deposition, but could be a combination of “forward” and “reverse” as well as lateral movement. Further, depending on process parameters and materials used, the “second pass” may be undertaken on the same apparatus used for coating, or on a second, similar apparatus, so that coating occurs on one apparatus, and coating removal on a second apparatus. Many, multiple successive passes may be necessary to effect complete removal of coating in an area.

During or after the “second pass” represented by step 109, remover 13 is actuated to spray or deposit solvent onto the extrudate or coating on the substrate to at least partially remove the coating in a selected area (rather than complete removal, a “thinning” of the coating could be accomplished), at step 111. As described previously, a solvent selected for compatibility with the extrudate (or an abrasive laden fluid if the extrudate has no solvent, or a combination of solvent and abrasive fluid) is sprayed or deposited by nozzle 27. The amount and flow rate of the solvent fluid is controlled by controller 12 and associated valves. A heater in the form of cartridge or jacket resistance heating (or similar) elements may be provided on remover 13 or its fluid conduits if the extrudate or coating material benefits from heating of the solvent to improve the removal performance. Movement of remover 13 is controlled by controller 12, carriage 9, crossbar 11, and associated motion and control components 17, 19, 21, 31, and the rotary union 23 to apply the solvent to a selected area of the coated substrate, thereby allowing selective removal of the coating or extrudate from the substrate.

Optionally, if a multi-layered or 3-dimensional shape is desired, a branch is taken in the process at step 113. It should be noted that even typical, single layer thin-film coatings have a 3-dimensional aspect (a “z” thickness as well as “x” and “y” dimensions). For purposes of this application, 3-dimensional means “thicker” than typical thin-film coatings (having a thickness of less than 1 μm), whether that thickness is achieved by multiple layers of the same or different thin-film coatings, or by a single layer applied at greater thickness. At this branch, if a multi-layer or 3-D shape is desired, “reverse” movement of the carriage is again undertaken to make a “third” or subsequent “pass” or “passes” over the coated (or coated and selectively removed) substrate. Additional layers of extrudate, of the same or a different material, can be deposited and selectively removed as described above in connection with steps 103 to 111.

If no multi-layer shape is desired, or formation of the multi-layer shape by selective extrusion and removal is complete, the process ends at step 117. Thus, the method and apparatus of the present invention provides the ability to “start” and “stop” the extrusion process selectively along with the ability to selectively remove extrudate, which greatly increases the flexibility of the coating apparatus and method. The conventional positive attributes of the extrusion process are preserved.

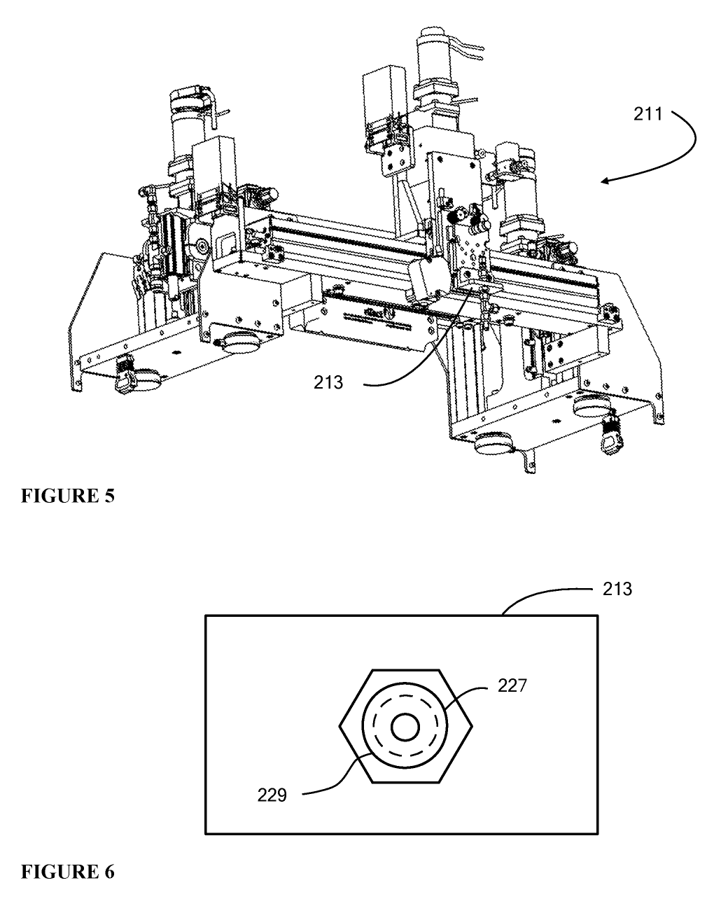

FIG. 5 is a perspective view of a carriage 211, similar to that of FIGS. 1 and 2, carrying an extrudate remover assembly 213 according to another embodiment of the invention. In this embodiment, solvent nozzle 227 and spray-capture or exhaust or suction tube 229 are coaxial with one another as shown in greater detail in FIG. 6. Extrudate remover 213 is movable with carriage 211 and operates generally as described in connection with FIGS. 1 through 4.

FIG. 6 is a plan view, looking upward, of a nozzle assembly 215 of extrudate remover 213 that illustrates the concentricity of solvent nozzle 227 and suction tube 229. Although illustrated as having round or circular cross-sections that are coaxial or concentric with each other, nozzle 227 and tube 229 may also be rectilinear, oval, elliptical, etc. and symmetrical or asymmetrical in cross-section, depending on the application and flow characteristics of the solvent medium. Nozzle 227 and tube 229 may have different cross-sections, but may be coaxial so that an exterior structure surrounds an interior structure. Multiple tubes 229 may be provided, all concentric or coaxial with one another or surrounding nozzle 227 and each other, as indicated by the phantom line in FIG. 6. In a multiple-tube embodiment, all of the tubes surrounding nozzle 227 may be configured to apply suction or vacuum (to deliver selectively greater suction, as by applying vacuum through one or more tubes), or some may be configured to deliver solvent in addition to nozzle 227.

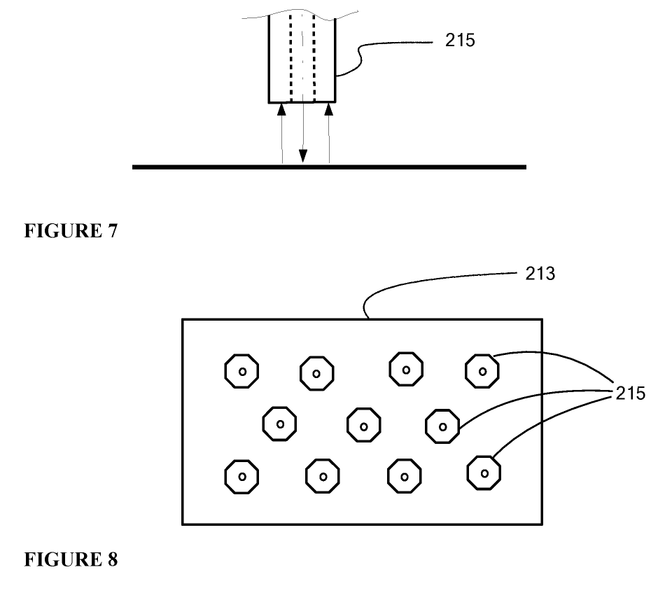

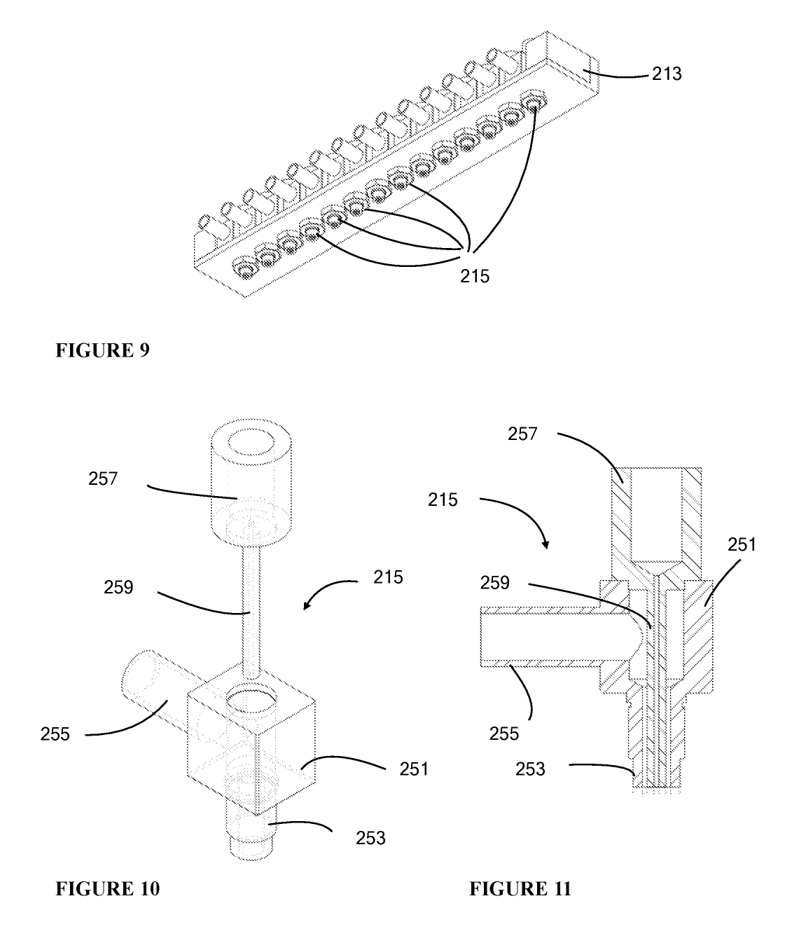

In a preferred embodiment, solvent nozzle 227 has an inner diameter of 0.055 inch and suction tube 229 has an inner diameter of 0.288. This configuration is useful for PEDOT polymers. As indicated in FIG. 7, nozzle assembly 215 is oriented perpendicularly above a substrate at a selected and controlled distance (z-axis). Solvent, whether chemical, abrasive, or a combination, is delivered along a nozzle axis (parallel to the z-axis) by solvent nozzle 227 and suction or vacuum is applied through the annulus between the exterior of solvent nozzle 227 and suction or exhaust tube 229, again along the nozzle axis.

Outer, exhaust tube 229 completely surrounds the inner solvent nozzle 227. This completely contains solvent flow, avoiding splashing or other forms of solvent migration outside of the target removal area. Uncontained solvent splashing or spray could adversely affect the surrounding coated areas, resulting in unacceptable yield loss.

The concentric nozzles can be made in a range of sizes, providing a line removal width of less than 1 mm to over 10 mm. Non-circular nozzle cross-sections, such as ovals, can provide longer solvent exposure time (when traveling in the direction parallel to the long axis of the oval) or a wider removal stripe (when traveling in the direction perpendicular, or off-axis, to the long axis of the oval).

Because of the relatively small “footprint” of nozzle assemblies 215, multiple sets of such nozzles 215 may be arranged in overlapping linear, or pure linear arrays as depicted in FIGS. 8 (multiple overlapping linear rows) and 9 (a single linear row). If this linear array is traveling in a direction parallel to a line of nozzles, then the speed of travel can be increased due to the multiple, sequential exposure to the nozzles. A slightly off-axis travel direction can provide a wider removal stripe, while still having multiple, overlapping exposure to the nozzles. Multiple “passes,” as described above may be made, with incremental changes in the y-axis, to achieve selected removal patterns. A larger degree of off-axis direction (up to perpendicular) can provide a striped removal pattern. A large number of nozzles can be used in an array to provide striped removal in a single pass across the substrate (in either direction on the substrate). Nozzle assemblies 215 may all terminate in the same plane or may be of differing projection.

FIGS. 10 and 11 depict a construction of a concentric or coaxial nozzle assembly in accordance with a preferred embodiment of the present invention. A main nozzle body 251 with a downwardly projecting main nozzle 253 has a central bore extending through it. A conduit boss 255 projects from the side of nozzle body 251 and has another bore extending therethrough and intersecting the central bore in nozzle body 251 and nozzle 253.

A secondary nozzle body 257 and downwardly extending nozzle 259 are received in the central bore of nozzle body 251 and is concentrically or coaxially located therein by a reduced-diameter portion of secondary nozzle body 257, which registers with the central bore to centralize and locate secondary nozzle 259 within main nozzle 253.

Upon assembly together, tubes or conduits may be attached to conduit boss 255 and secondary nozzle body 257 to supply suction/vacuum and solvent or extrudate remover to nozzles 253 and 259, which are concentric and coaxial, as described above. In a preferred embodiment, vacuum or suction is applied through boss 255 and main or outer nozzle 253, while extrudate remover is applied through inner or secondary nozzle 259. This arrangement may be reversed.

Nozzle assembly 215 is in close, controlled proximity to the substrate (distance typically controlled by a z-axis servo with laser-based height feedback). This close proximity helps in the full containment of the solvent, and provides for repeatable and predictable removal width.

Nozzle assembly 215 may be equipped with an ultrasonic transducer, to transfer ultrasonic energy through the solvent stream to the substrate, thus improving the removal rate and efficacy. The nozzle may be heated, thereby heating the solvent stream to the substrate, thus improving the removal rate and efficacy.

According to the method and apparatus of the present invention, discrete segments or very carefully selected areas can be deposited on to a substrate. The shape deposited being rectilinear or orthogonal as determined by a combination of die modification and software to control both material dispensing rate and movement relative to the substrate. By use of the techniques outlined above and in combination with or incorporating as part of the coater design, a shape patterning technique such as the material removal system with movement in the x, y and z axis and incorporating full 360 degree rotation about the z axis complex shapes can be deposited onto the substrate. Complex shapes can be defined but are not exclusive to shapes other than simple quadrilaterals that can have n number of sides where n is greater than 2. The shapes may include interior and exterior acute and obtuse angles as well as linear, curvilinear and circular forms.

Using the techniques outlined above, the method can be used to deposit both 2-D (single coating layer) and 3-D (single, “thick” or multiple coating layer) complex shapes onto a substrate—where a 2-D shape is regarded as a thin film with height in the z-axis less than or equal to 1 μm. A 3-D shape would have a height of greater than 1 μm in the z axis but these are not exclusive definitions. By using materials of differing viscosity, differing surface energy, thixotropy and other pertinent material properties, 2-D and 3-D complex shapes can be deposited.

By using the method outlined above and controlling the material properties and substrate properties, 2-D and 3-D shapes can be deposited that may (or may not) involve a curing step such as but not exclusive to actinic radiation, thermal radiation, IR radiation, e-beam radiation, and evaporation.

By using the method outlined above, controlling the material properties, substrate properties and possible cure step, the technique can be used as a wet or dry technique. Furthermore, the step can be included to be done “on the fly” or discrete quadrilaterals deposited which are then converted to a “complex shape” as an additional step. The technique described above can then be used to build up multiple layers. The multiple layers can be wet processed or dry processed. The layers may be active or passive, for example planarizing or conformal layers.

The method may be used to form the discrete electroless deposition of metals onto a substrate. The substrate and/or the deposited material may act as the catalyst for the electroless deposition.

The substrate may be active or passive by integral or exterior means such as, but not exclusive to, a power source, light source, radiation source, magnetic field, electrical field, stored energy system such as spring or capacitor, dynamo or gravity fed.

Multiple layers may result from separate feeds charged to the die head through a single or multi-feed pump or combination of feeds and pumps. The multiple layers can be built up as part of a process using one or more coaters incorporating the techniques described above. The multiple layers can be simple quadrilaterals or complex shapes.

The multiple layers can be patterned as part of the process and is not exclusive to laser patterning or e-beam patterning or any other direct write technique. The process may also include solvent etching of the substrate. The multiple layers can be patterned as part of a separate process such as, but not exclusive to, photolithography, engraving, printing techniques, solvent etch techniques, or other forms of physical removal.

The use of the techniques above can be used in the manufacture of discrete segments or complex shapes that act as filters be it optical, acoustic, polarizing, light guides, self assembly layers, or holographic.

The use of the techniques above may result in single or multiple layers that are active or passive.

The single or multiple layers can be used for data storage such as, but not exclusive to, holographic or digital data that can be addressed directly as part of the process or separately as an additional process.

The single or multiple layers can contain electron generating species activated by incident radiation or other energy transfer mechanism such as an electric, magnetic current—heat or shock energy such as that used in piezoelectric systems.

The single or multiple layers can be energy emissive or energy transferring such as to include, but not exclusive to, photovoltaic and other solar radiation gathering devices, or used in illumination such as, but not exclusive to, OLED and PLED devices and other solid state electrical devices.

The use of the techniques above can be used to make discrete electronic circuits such as, but not exclusive to, RFID circuits, transistors and other switching media.

The techniques outlined above can be used in the manufacture of more complex devices by the use of single or multiple layers to include, but not exclusive to, RFID, electronic circuits for backplane technology, semi-conductors for use in photovoltaics and OLED and PLED applications, electrophoretic, emissive reflective and other backplane technologies.

1. An apparatus for forming selectively coated areas on a planar substrate comprising:
a chuck configured to secure the coated substrate in selected position;
a coating remover arranged above the coated substrate to selectively remove portions of a coating from the substrate, the coating remover including:
a nozzle for delivering a coating-dissolution medium to the substrate, the nozzle having an axis along which the coating-dissolution material is delivered; and
an exhaust conduit for removing the coating-dissolution medium from the substrate, the exhaust conduit having an axis along which the coating-dissolution material is removed from the substrate, the exhaust conduit surrounding the nozzle;
a controller configured to selectively control relative motion between the substrate and the coating remover in at least x and y axes parallel to the substrate.

2. The apparatus of claim 1, wherein the coating remover is mounted on a carriage that moves relative to the substrate.

3. The apparatus of claim 1, wherein the nozzle and exhaust conduit are circular in cross-section and are concentric and coaxial with one another.

4. The apparatus of claim 2, further comprising:
an extruder carried by the carriage to deposit coating material on the substrate.

5. The apparatus of claim 1, wherein the coating remover comprises a plurality of nozzles arranged in an array, each nozzle surrounded by an exhaust conduit.

5. A method of removing a previously applied coating from a generally planar substrate in a selected pattern, the method comprising the steps of:
positioning a coating remover above the substrate in a selected location relative to the substrate;
dispensing a coating-dissolution medium onto the substrate along a dispensing axis generally perpendicular to the substrate;
removing the coating-dissolution medium from the substrate by application of vacuum, the vacuum applied along the dispensing axis; and
moving the coating remover in x and y axes relative to the substrate to another selected location and repeating the dispensing and removing steps until coating is removed from the substrate in the selected pattern.

6. The method of claim 5, wherein:
the step of dispensing the coating-dissolution medium is accomplished by a nozzle; and
the step of removing the coating-dissolution medium is accomplished by a vacuum conduit that surrounds the nozzle.

7. The method of claim 6, wherein the steps of dispensing and removing the coating-dissolution medium are accomplished by a plurality of nozzles arranged in an array, each nozzle surrounded by a vacuum conduit.
